(19) United States
(12) Patent Application Publication
(10) Pub. No.: US 2014/0044475 A1
(43) Pub. Date: Feb. 13, 2014

(54) BASE OR MOUNTING FRAME FOR AN ELECTRICAL ENCLOSURE OR A RACK

(71) Applicants: Dennis Broemstrup, Osnabrueck (DE); Siegfried Boehme, Wolfen (DE); Heiko Holighaus, Eschenburg (DE); Matthias Mueller, Dillenburg (DE); Michael Schnakenberg, Wallenhorst (DE)

(72) Inventors: Dennis Broemstrup, Osnabrueck (DE); Siegfried Boehme, Wolfen (DE); Heiko Holighaus, Eschenburg (DE); Matthias Mueller, Dillenburg (DE); Michael Schnakenberg, Wallenhorst (DE)

(73) Assignee: Rittal GmbH & Co. KG, Herborn (DE)

(21) Appl. No.: 13/261,720

(22) PCT Filed: Feb. 17, 2012
(86) PCT No.: PCT/DE12/00156

§ 371 Date: Oct. 28, 2013

(51) Int. Cl. H05K 7/14

(52) U.S. Cl. CPC H05K 7/1489
USPC 403/205

(57) ABSTRACT

The invention relates to a base or a mounting frame for an electrical enclosure or a rack, comprising mounting pieces which are arranged, as corner pieces, in the corner regions of a rectangle or square that extends in an x-y plane, said mounting pieces being produced in a respective shaping process and comprising first and second mounting faces which lie outside with respect to the rectangle or square, which extend in the x direction and in the y direction at a right angle thereto and which extend in a space direction z at a right angle to the x-y plane, wherein sections of a system of covers are brought into contact with the mounting faces, said covers having lateral covers with cover walls that are flat on the exterior and that have reinforcing ribs extending longitudinally on the interior, and being fastened to receiving structures of the mounting pieces by connecting means. Benefits in the installation process are achieved in that the lateral covers have cover fastening elements formed onto the interior of the lateral covers and are fastened directly or indirectly to the receiving structures of the mounting pieces by means of said cover fastening elements.

The invention relates to a socket or mounting frame for a switchgear cabinet or a rack, comprising mounting pieces which are arranged, as corner pieces, in the corner regions of a rectangle or square that extends in a x-y plane, said mounting pieces being produced in a respective shaping process and comprising first and second mounting faces which lie outside with respect to the rectangle or square, which extend in the x direction and in the y direction at a right angle thereto and which extend in a space direction z at a right angle to the x-y plane, wherein sections of a system of covers are brought into contact with the mounting faces, said covers having lateral covers with cover walls that are flat on the exterior and that have reinforcing ribs extending longitudinally on the interior, and being fastened to receiving structures of the mounting pieces by connecting means.

A socket or mounting frame for a switchgear cabinet of this type is disclosed in DE 194 34 551 C1. In the corner regions of the socket, which is rectangular in a top view, mounting pieces are arranged as corner pieces which are connected to another by means of lateral covers. The corner pieces are configured as upright profile sections made of extruded aluminum profile comprising several partly open and partly closed cavities running in longitudinal direction of the profile and being confined by wall sections. Mounting faces of the corner pieces which are outside with respect to the socket comprise slots running in longitudinal direction of the profile leading to rear side cavities which form T-shaped fastening grooves via which the covers are mounted by means of screws which engage nuts arranged within the grooves. Such configuration results in a considerable mounting effort, in particular if the covers must be removed and re-installed for installation purposes e.g. at locations which are difficult to access.

In another socket shown in EP 0 725 464 B1, the corner pieces comprise an upper and a lower connecting plate which are connected to another by means of rib-shaped vertical walls, wherein laterally protruding fastening plates having bores are provided which covers are mounted. Also this configuration can lead to unfavorable mounting effort.

Further sockets which can be equipped with covers, are shown in DE 10 2007 013 520 A1, WO 02/080322 A1, DE 37 10 567 C2, DE 84 10 203 U1, DE 43 10 079 C2, DE 93 08 162 U1, DE 103 28 407 A1 and EP 0 686 316 B1. Those known sockets comprise corner pieces formed as angled punched/bent parts to which the covers can be attached, while also a considerable mounting effort is generated.

It is the object of the invention to provide a socket or mounting frame of the type mentioned in the introductory, which improved mounting possibilities are achieved.

This object is solved by the features of claim 1. It is provided that the lateral covers have cover fastening elements formed onto the interior of the lateral covers and are fastened directly or indirectly to the receiving structures of the mounting pieces by means of said cover fastening elements.

Accordingly, the covers can be easily mounted and easily removed, wherein fastening elements must not be mounted with much labour and are also prevented to get lost. Thereby e.g. installation work in particular at locations which are difficult to access, is simplified.

Advantageous measures for production and also for mounting purposes consist in that also the cover fastening element extend in longitudinal direction of the lateral covers and that the lateral covers are made of metal or preferably of plastics in an extrusion process.

Handling during assembling is further promoted in that the cover fastening elements are formed as clip elements or locking elements having a flat insert slope and a steeplocking step and are engaged or can be engaged, by means of resilient deflection, with respectively adapted receiving structures at the mounting faces of the mounting pieces or at other intermediate elements, such as mounting rail or C-rail, extending between the mounting pieces and mounted thereto with their end sections, to fix the lateral covers, wherein the cover fastening elements and/or the receiving structures can be resiliently deflected.

For mounting, also those measures have an advantage that the system of covers also includes corner covers which are configured to cover the outer corner regions of the mounting pieces.

Easy mounting is achieved in that the corner covers are provided with corner cover fastening elements formed onto the interior thereof by which they can be fastened directly or indirectly to associated receiving structures of the mounting piece.

Those measures contribute to an advantageous production that also the corner covers are made of metal or preferably of plastics and are provided with reinforcing structures formed onto the interior of plate-shaped corner cover walls thereof.

Those measures that the corner covers, on order to achieve at a smooth transition from an exterior thereof to the exterior of the lateral covers, comprise end sections overlapping facing and sections of the lateral covers, which are inwardly offset by the thickness of the cover wall in a z-shaped manner, positively contribute to the optical designed also to a simple and unique arrangement of the covers without producing undesired gaps at transition places.

Further advantages for mounting are achieved in that the receiving structures of the mounting pieces comprise receiving chambers running parallel to the relevant mounting face, which are at least partly surrounded by wall sections running in their orientation direction and which are open at their front ends facing away from each other, and/or that the receiving structures comprise receiving ribs, receiving grooves, receiving bars, other protrusions and/or other depressions and that at least a proportion of the receiving structures is provided with fastening means, in particular locking means formed thereon, which can be engaged with the covers and/or with intermediate elements extending between the mounting pieces.

By the measure that the mounting pieces terminate in z direction in a first and a second base face oriented in the x-y plane, the second base face being parallel and spaced apart from the first base face by a distance, both forming the outer face of at least a first and at least a second base wall section and that the mounting faces are spaced apart from another at their ends facing towards another and form a first corner space in the relevant first virtual corner region of the mounting piece which can be covered with the covers of the system, advantageous mounting possibilities are offered in particular also in the corner regions, where installation elements can be mounted beneficially and in a systematic sequence a free space remains which complements a free space existing in the edge region of an optional frame work neighboring in z direction.

Further advantageous measures for mounting consist in that further wall sections are coupled to the interior of the ends of the first and second mounting face, which ends are facing away from another, said wall sections being integrally connected and leave a second corner space between their ends facing towards another, which is confined in z direction by the first and the second base wall section. For example, at a base wall section present in the second corners space, an anchoring means having an anchoring claw for fastening the socket to a supporting face can be advantageously engaged.

For handling and fabrication, further advantageous measures consist in that the mounting pieces are formed as block-like plastic molded parts.

Further embodiment options are achieved in that for producing a frame of double or multiple heights, two or more mounting pieces are respectively arranged in the corner regions in said direction and are connected to one another. It is advantageous that the mounting pieces comprise complementary receiving structures on their opposite base faces by which they can be positioned in a row with outer contours aligned in z direction. Bores running in z direction which are present in mounting pieces in a row and which are aligned with another may be used advantageously for connection, or there are gaging locking elements or other connection elements acting in z direction.

The invention will be explained below with the aid of exemplary embodiments with reference to the drawing. There are shown in:

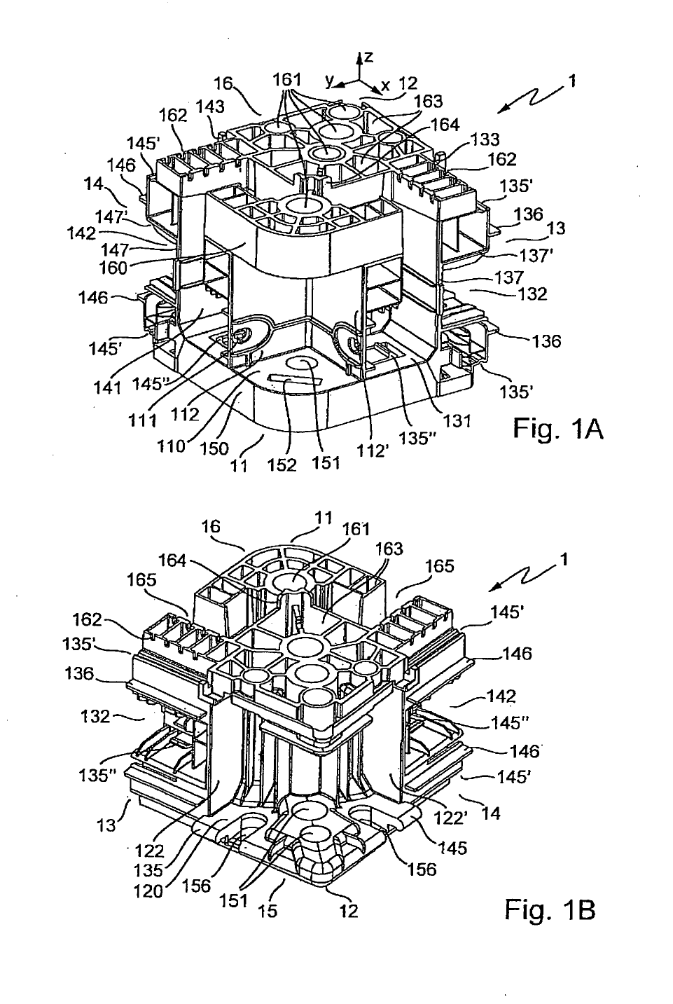

FIGS. 1A and 1B illustrations of a mounting piece in a perspective view onto two opposite corner regions,

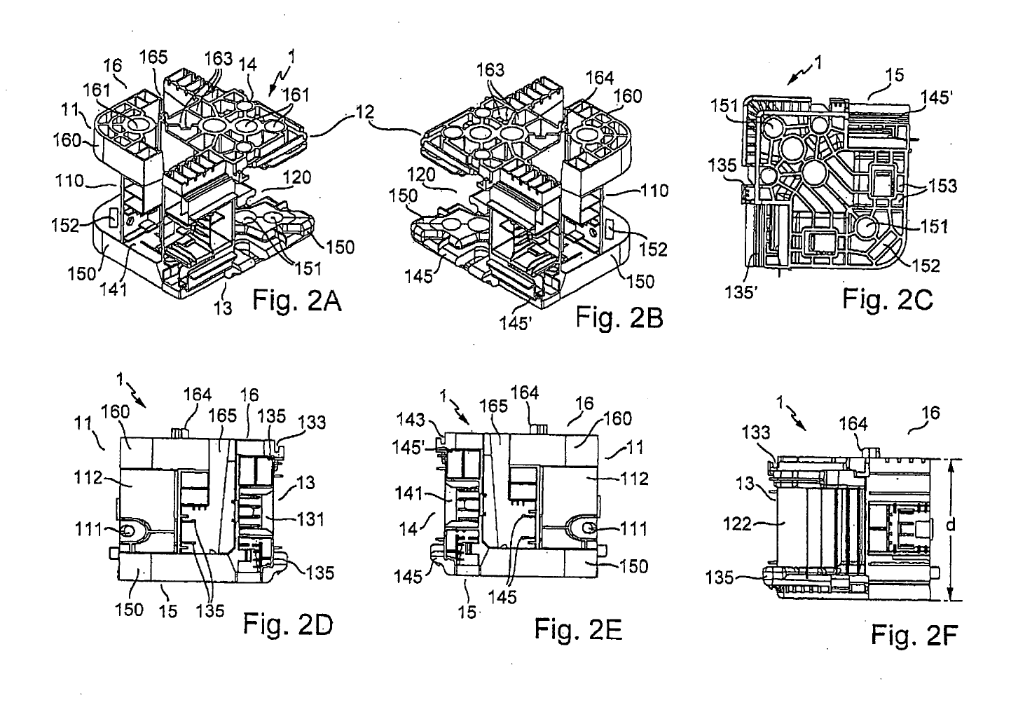

FIGS. 2A and 2B further perspective views of the mounting piece (with reference to a mounting state from the inwardly left hand side and inwardly right hand side, respectively),

FIGS. 2C to 2F further different views of the mounting piece (with reference to a mounted state seen from downward, from an inwardly left hand side, from an inwardly right hand side or in a front view, respectively),

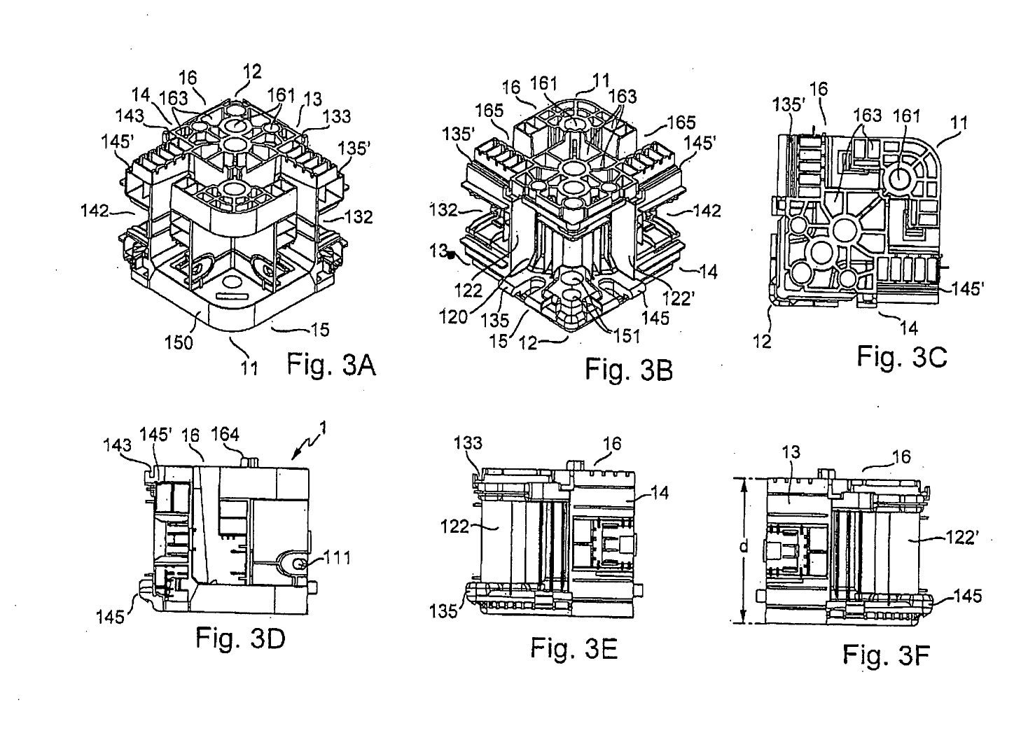

FIGS. 3A and 3B further perspective views of the mounting piece (with reference to a mounted state seen from inwardly or from outwardly, respectively),

FIGS. 3C to 3F different views of the mounting piece (with reference to a mounted state seen from the top, from the right hand side, from the front side or from the left hand side, respectively),

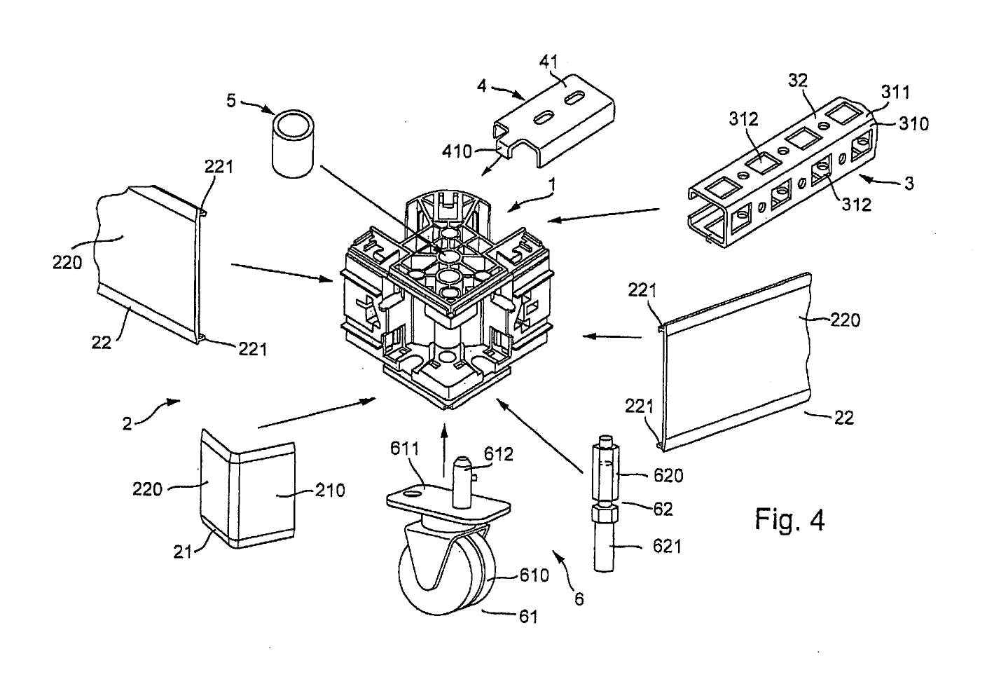

FIG. 4 the mounting piece with various mounting elements to be fixed thereto in a perspective view,

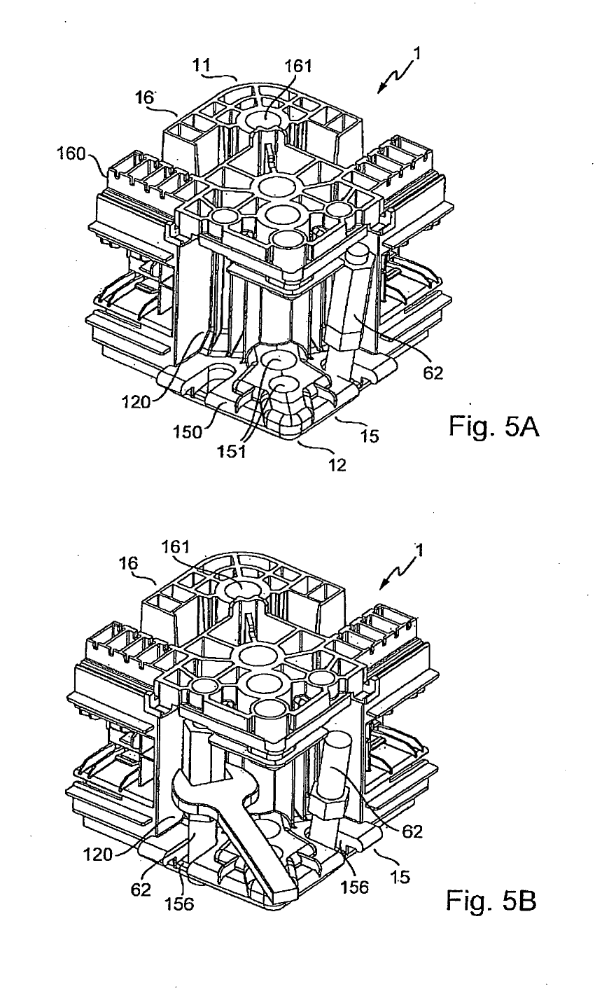

FIGS. 5A and 5B perspective views of a mounting piece having leveling elements arranged in a corner region during an assembling procedure,

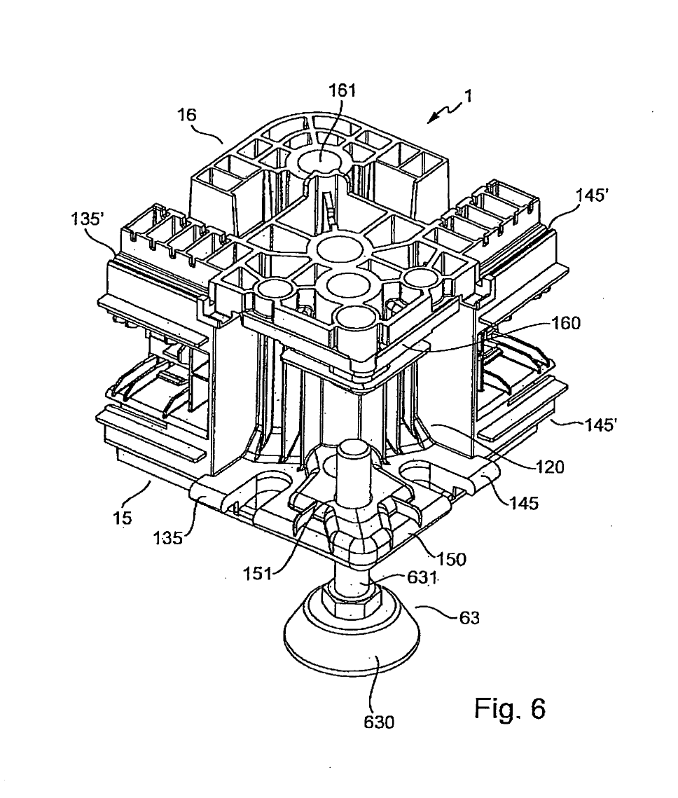

FIG. 6 the mounting piece in a perspective view having a support stand arranged in a corner region,

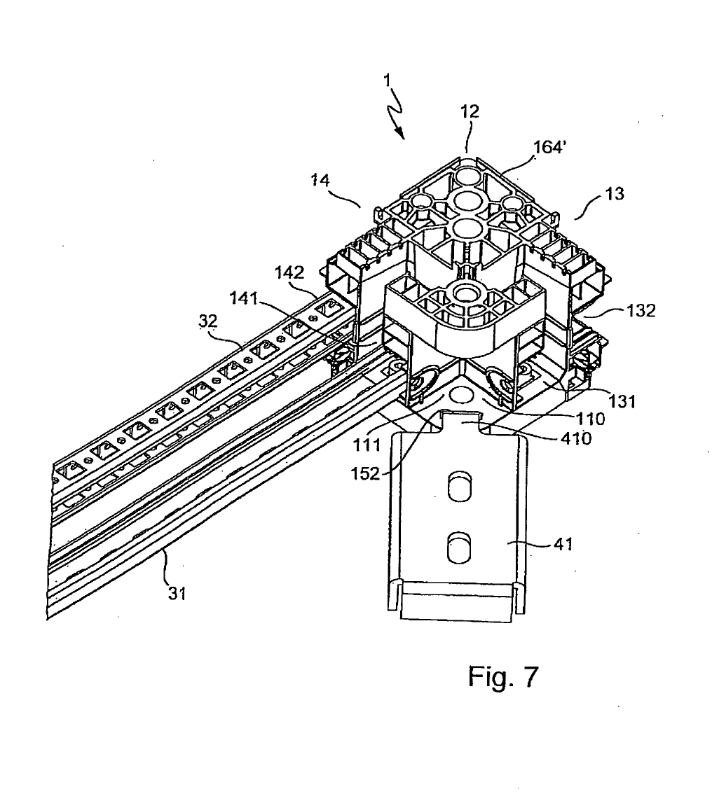

FIG. 7 a sectional view of a construction unit, for example a socket, having a mounting piece, a mounting rail and a C-shaped rail as well as anchoring means in a perspective view,

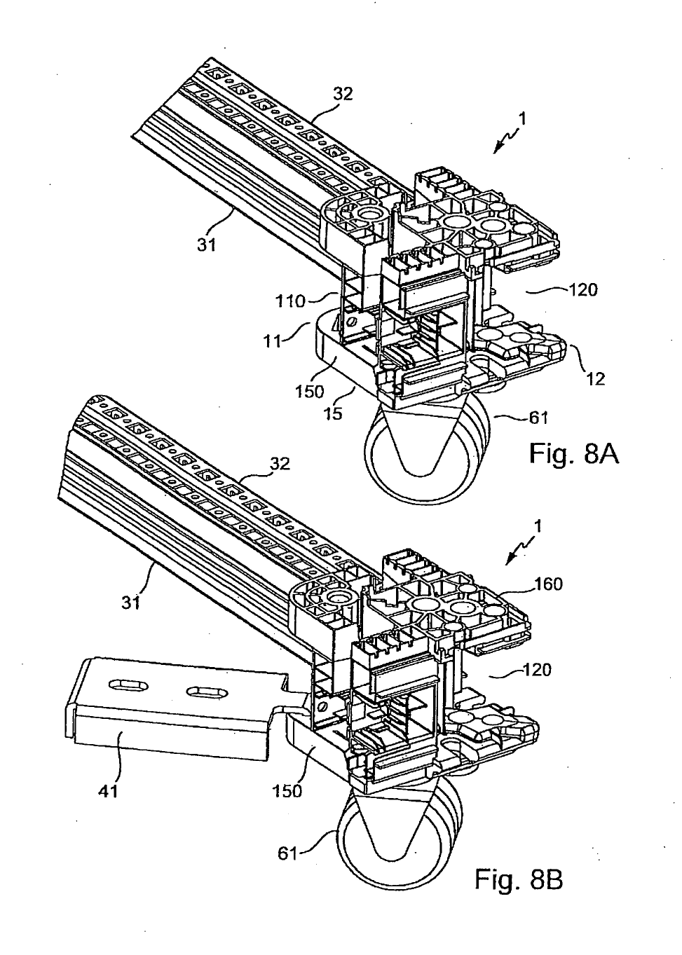

FIGS. 8A and 8B a sectional view of a construction unit having the mounting piece, a mounting rail, a C-rail and a castor unit mounted to the mounting piece, or, in addition, an anchoring means, respectively,

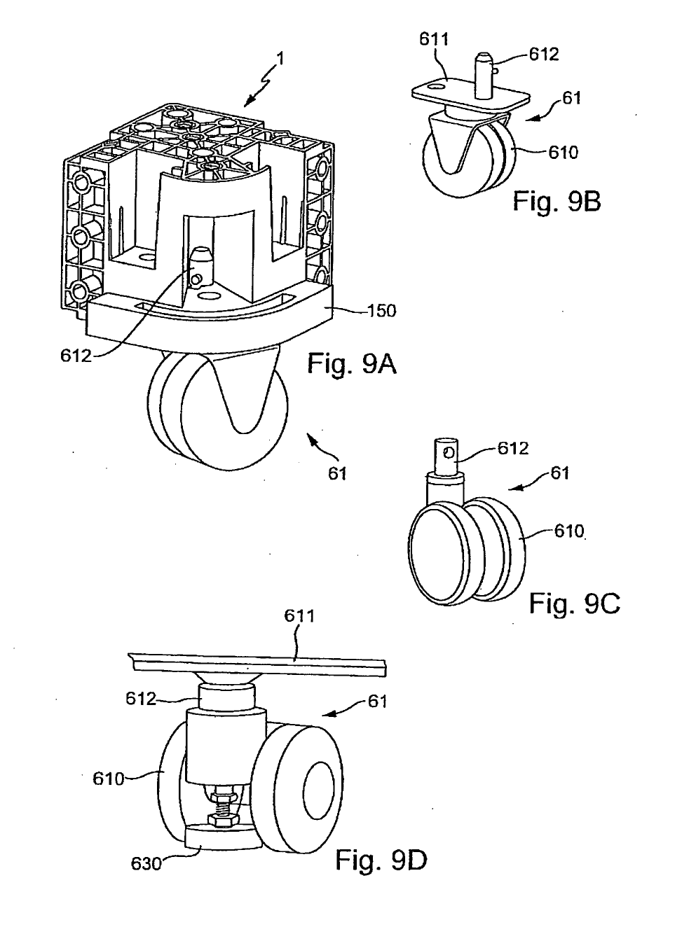

FIG. 9A the mounting piece having a mounted castor unit,

FIGS. 9B, 9C and 9D different castor units having holding members and support plates,

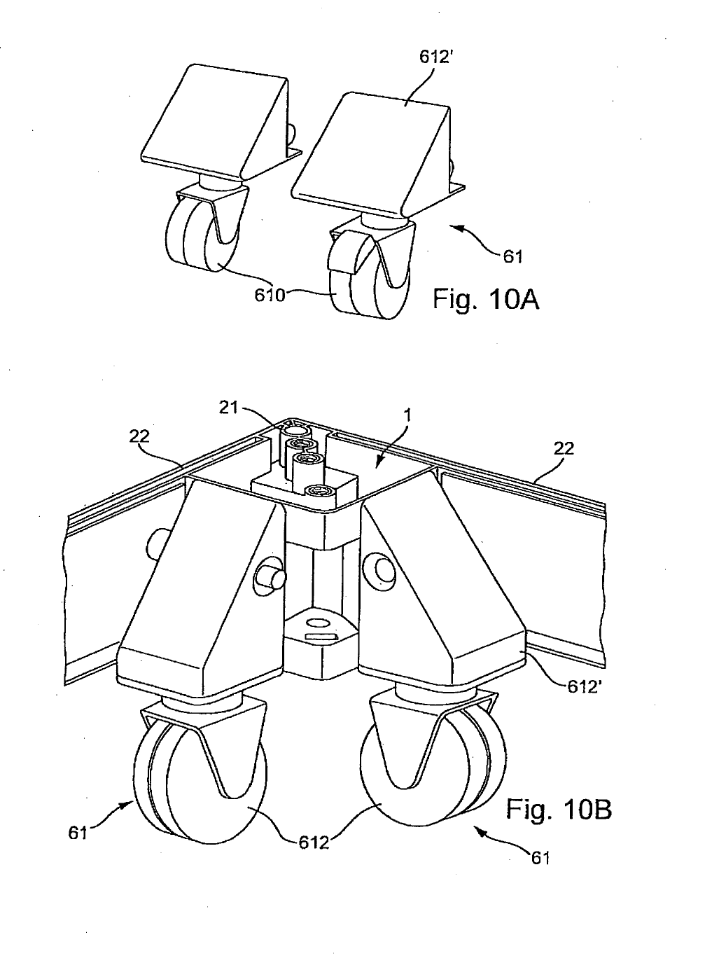

FIG. 10A another exemplary embodiment of a castor unit with holding member in a perspective view,

FIG. 10B examples for attaching a castor unit of FIG. 10A to the mounting piece,

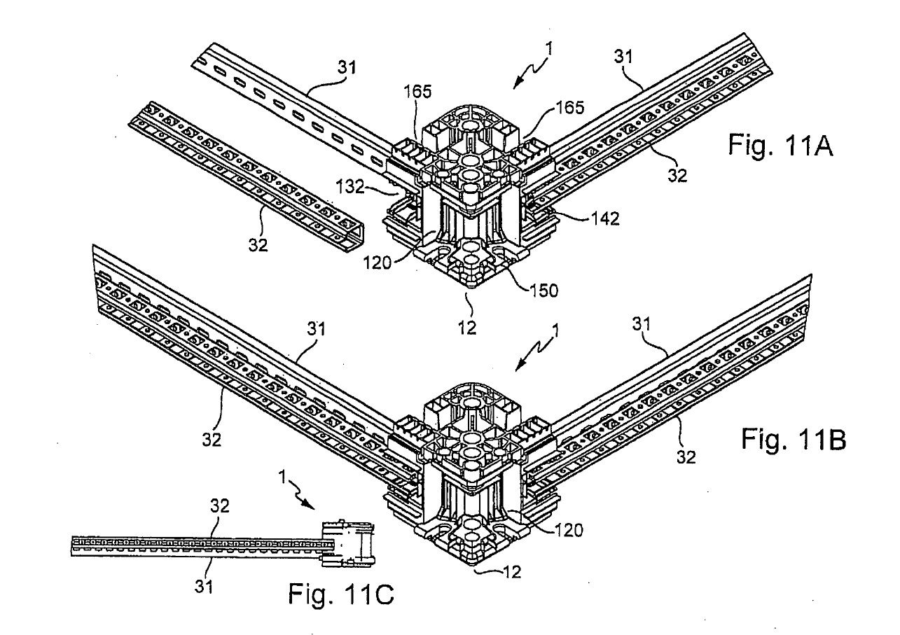

FIG. 11A a sectional view of a construction unit having a mounting piece and C-rails and a mounting rail fixed thereto as well as a mounting rail to be mounted thereto in a perspective view,

FIG. 11B the construction unit of FIG. 11A with mounted C-rails and mounting rails,

FIG. 11C the construction unit of FIG. 11A in a lateral view,

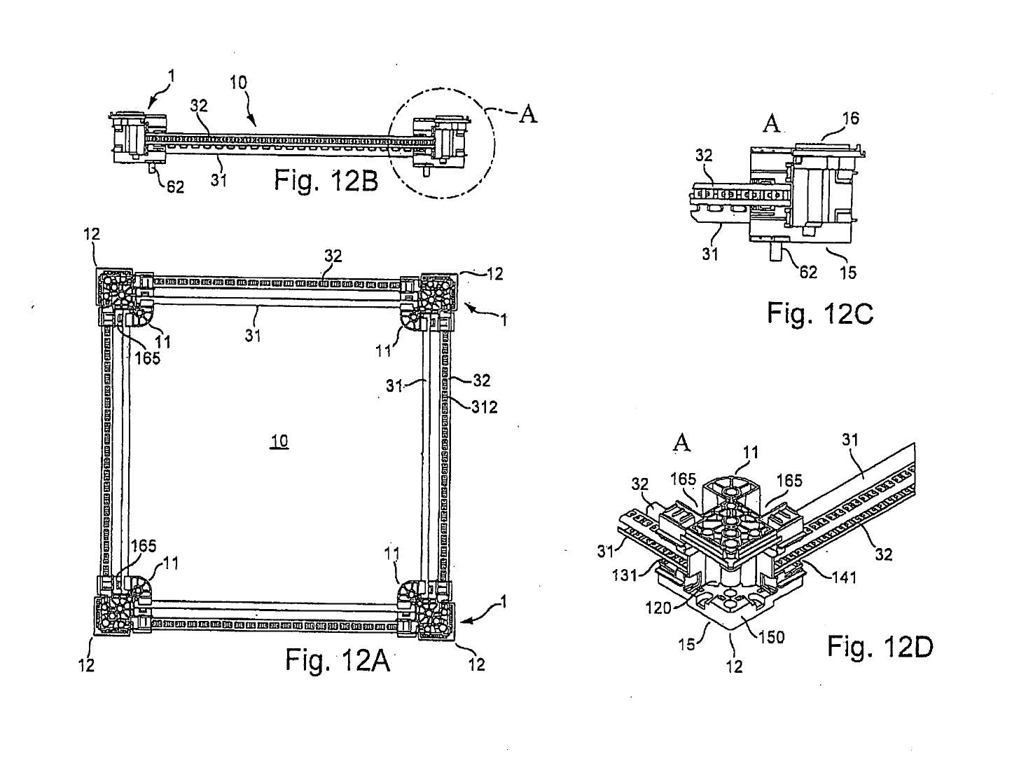

FIGS. 12A to 12D a construction unit which is square in a top view, having four mounting pieces as corner pieces as well as connecting intermediate elements in form of mounting rails and C-rails in a top view, lateral view and two enlarged views of a cut-out in the corner region,

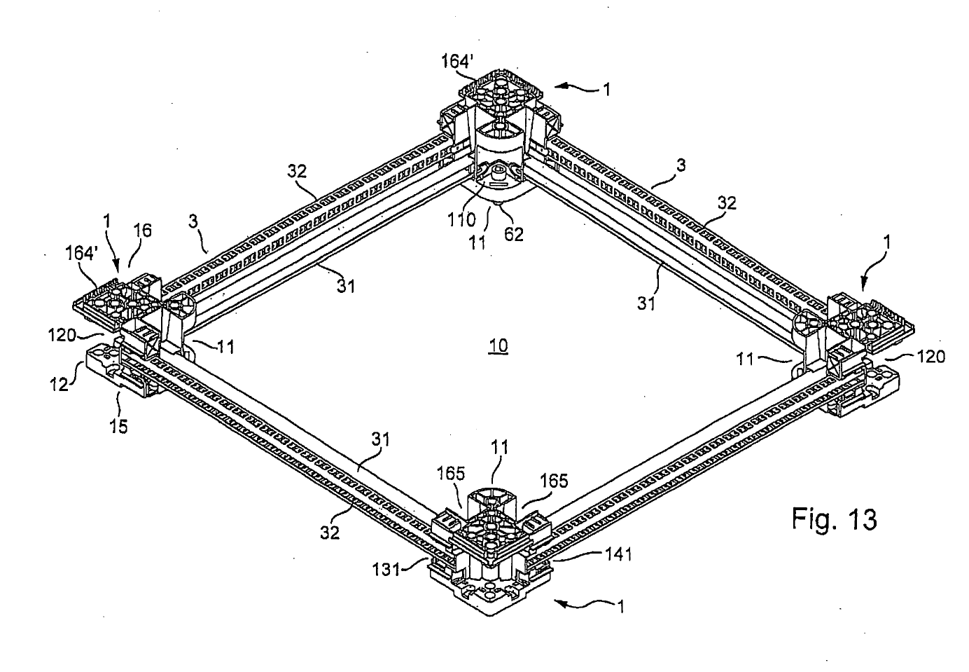

FIG. 13 the construction unit of FIG. 12A in a perspective view,

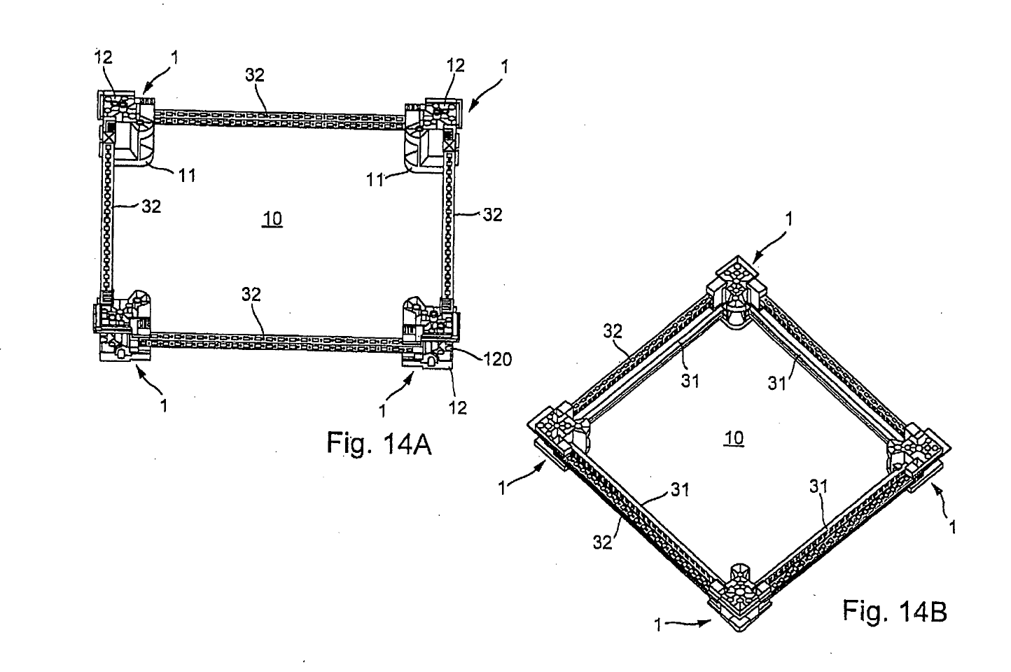

FIG. 14A a rectangular construction unit having mounting pieces arranged in the corner regions and connecting mounting rails in a perspective view,

FIG. 14B another exemplary embodiment of a square construction unit having mounting pieces arranged in the four corner regions and connecting mounting rails and C-rails in a perspective view,

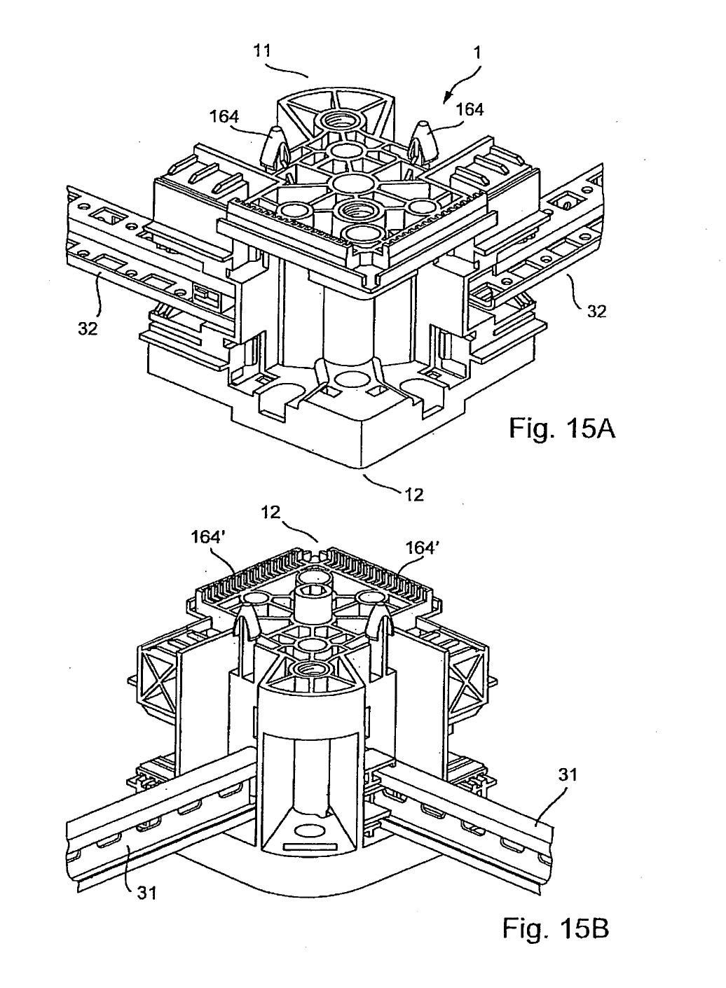

FIG. 15A as a cut-out, a construction unit in a perspective view, having a mounting piece and mounting rails fixed thereto in a perspective view from the outside,

FIG. 15B as a cut-out, a construction unit having a mounting piece and C-rails fixed thereto in a perspective view from the inside,

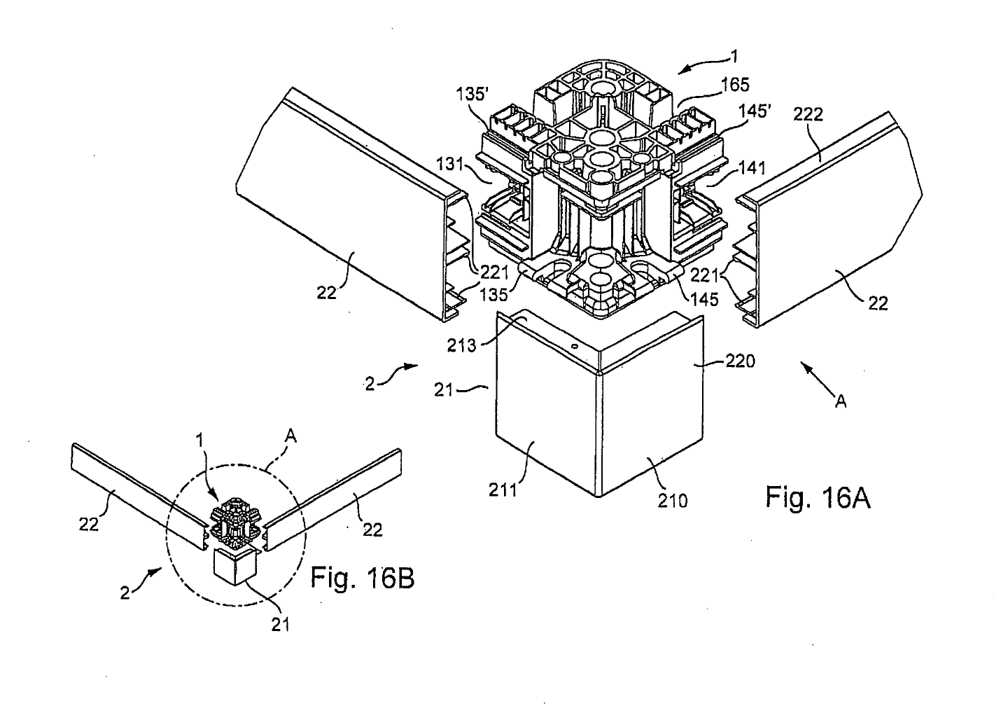

FIGS. 16A and 16B an exploded view of a corner region having a mounting piece and covers in a downsized and enlarged view,

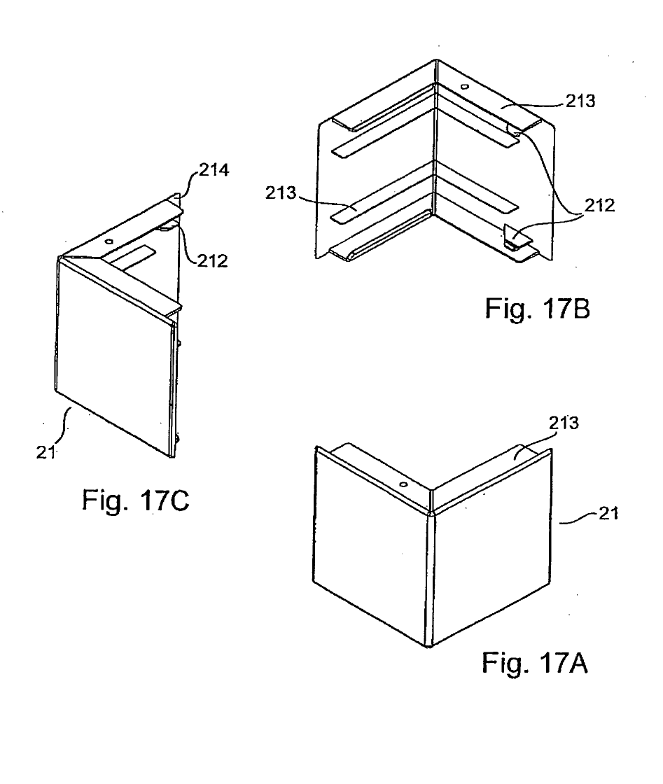

FIGS. 17A to 17C a corner cover in various perspective views,

FIGS. 17D to 17F further views of the corner cover,

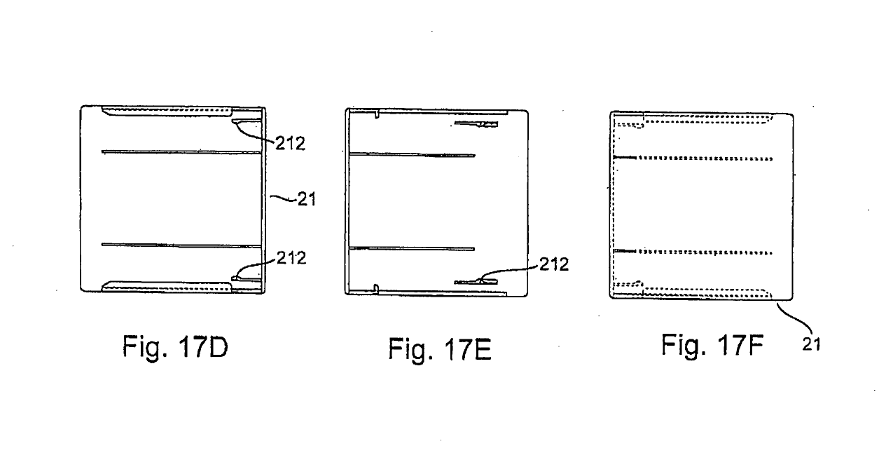

FIG. 18A a perspective view of a side cover,

FIG. 18B the lateral cover of FIG. 18A in a front end view,

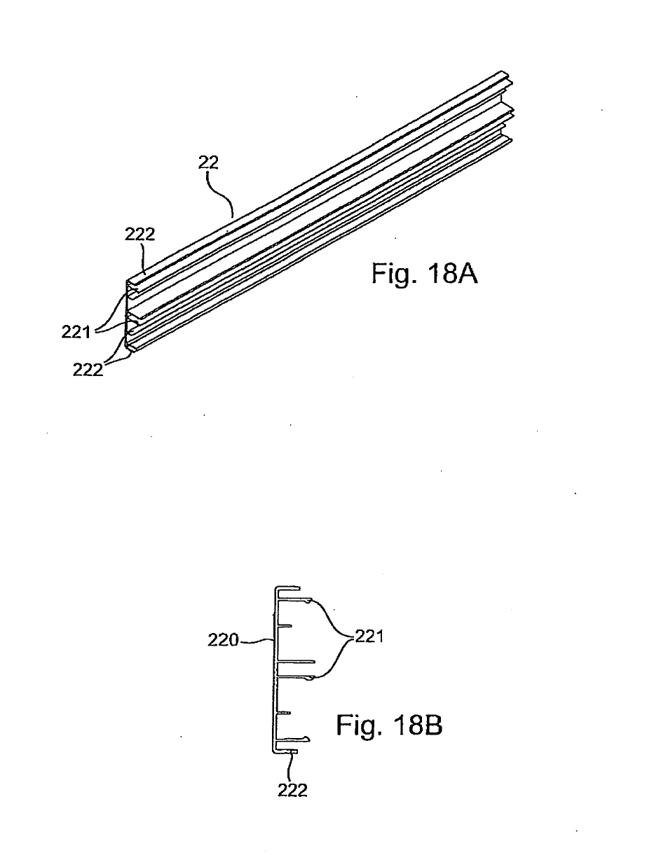

FIG. 19A a corner region of a construction unit, for example a socket, partly in an exploded view, having a mounting piece, C-rails mounted thereto and mounting rails, as well as covers, removed therefrom,

FIG. 19B a square construction unit, for example a socket, having mounting pieces arranged in four corner regions, mounting rails, C-rails as well as covers connecting these and mounted thereto,

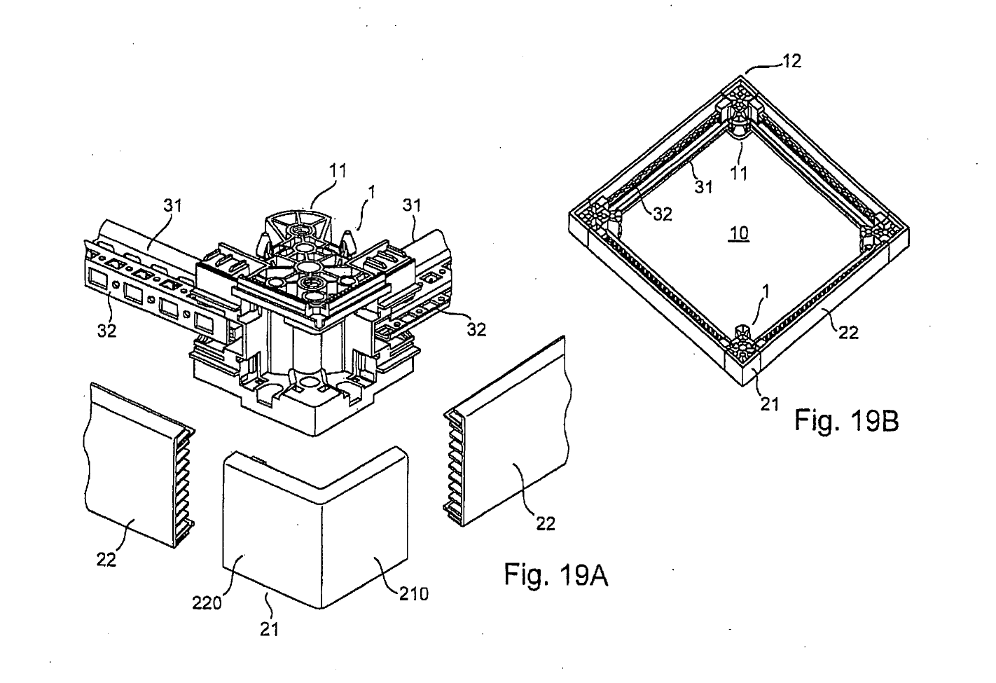

FIG. 20 a corner region of another construction unit having a mounting piece, different mounting rails fixed thereto as well as a C-rail mounted thereto,

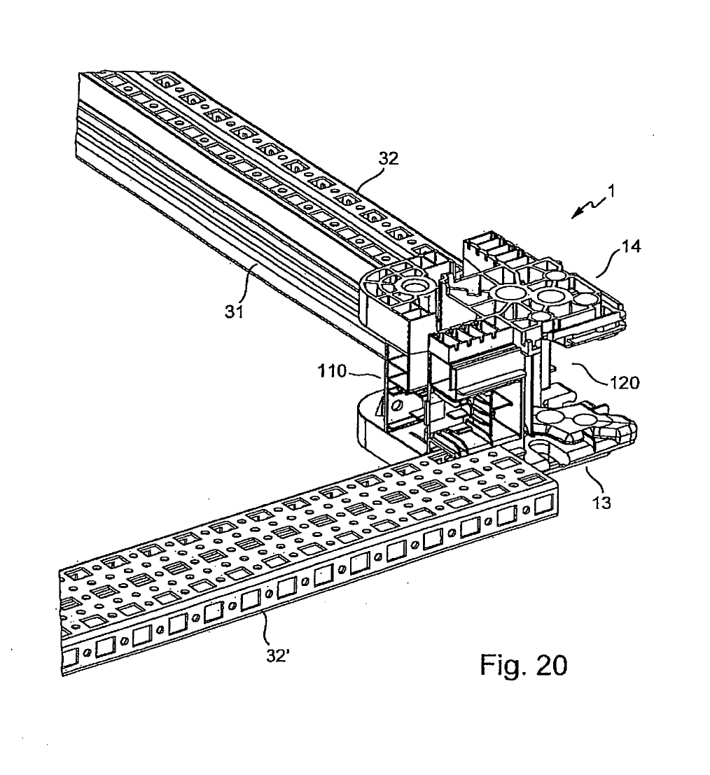

FIG. 21 a sectional view of two adjacent construction units in a row having two mounting pieces, a connecting mounting rail as well as another mounting rail fixed to a corner piece and a mounted C-rail,

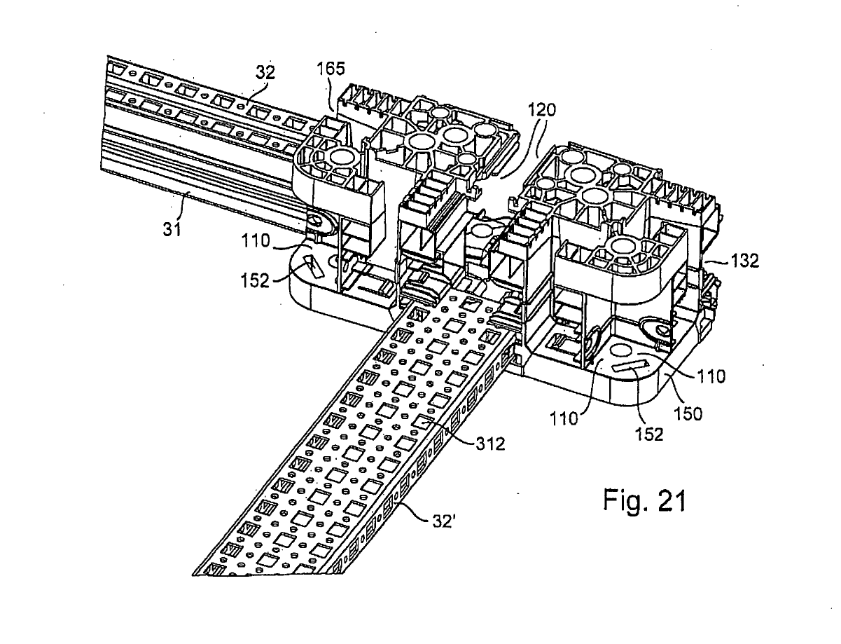

FIGS. 22A and 22B various adapter elements having different adapter plates to be mounted to a mounting piece,

FIG. 22C a sectional view of a framework of a switchgear cabinet having a castor unit mounted thereunder, and, further, on the left hand side thereof a cross section of a vertical frame profile,

FIG. 22D an example of a receiving unit, e.g. for a castor unit,

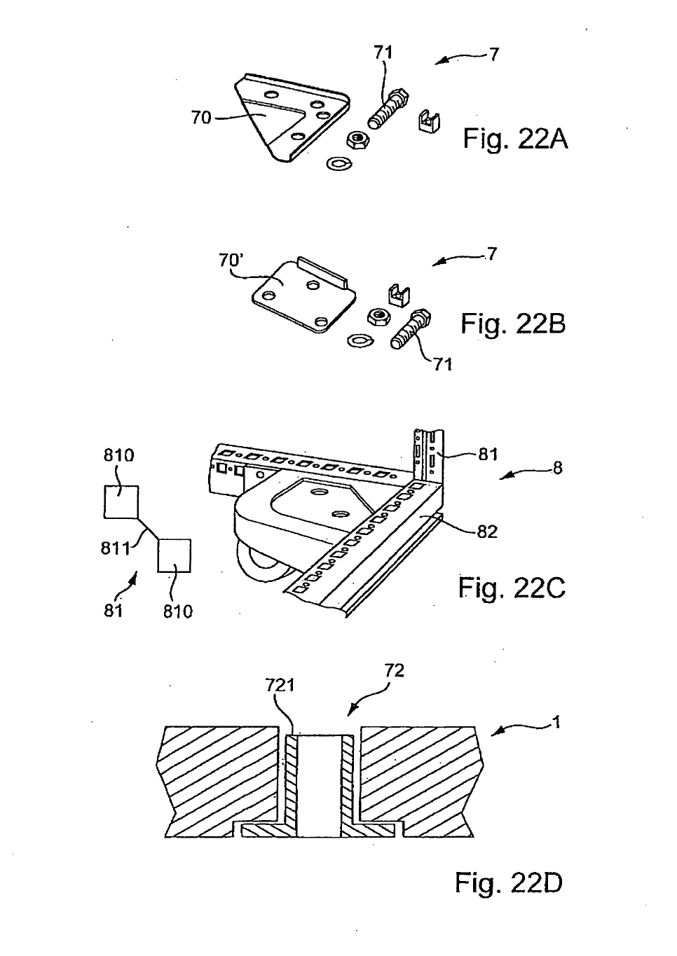

FIG. 23 two mounting pieces which are neighboring in z direction or height direction, respectively, and are connected to another,

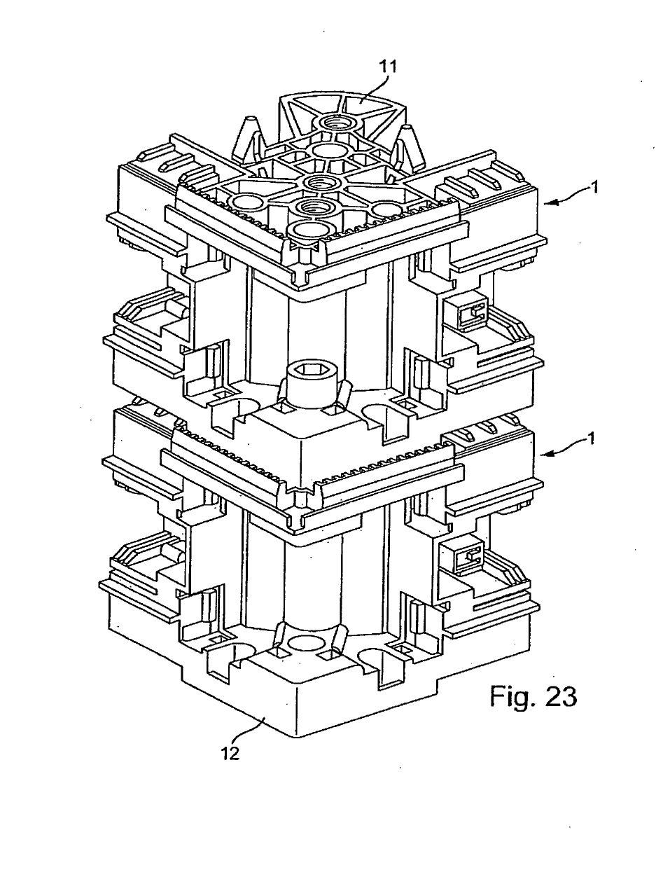

FIG. 24A a lower section of a framework of a switchgear cabinet or rack arranged on a socket having mounting pieces in a perspective view,

FIG. 24B a lateral view of the section of the framework of FIG. 24A which is fixed on the socket,

FIG. 24C a top view of a framework section of FIG. 24A mounted on a socket,

FIG. 24D a cut-out of a corner region with framework in the socket region of FIG. 24B,

FIG. 24E a cut-out of a corner region with framework in a socket region of FIG. 24D,

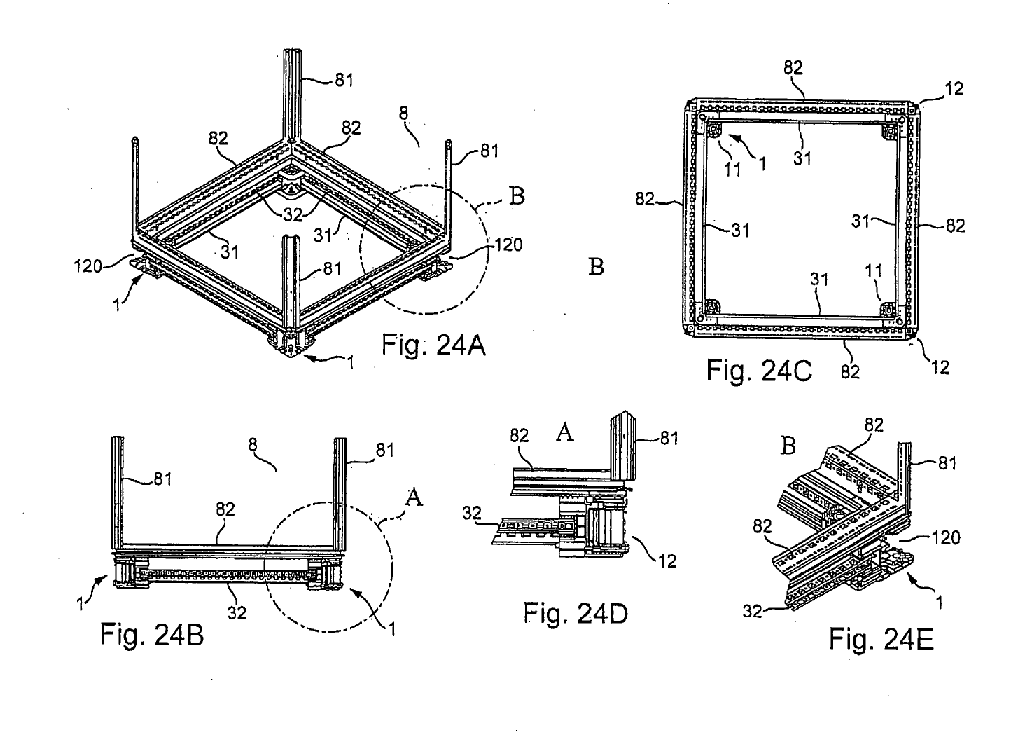

FIG. 25 a perspective view of a part of a framework mounted on a socket, partly in a perspective view,

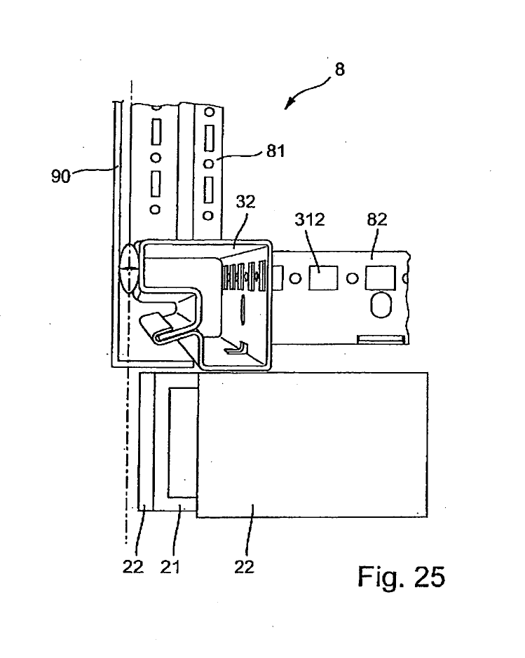

FIG. 26 a partial view of two neighboring sockets with adjacent framework fixed thereto, partly in a perspective view,

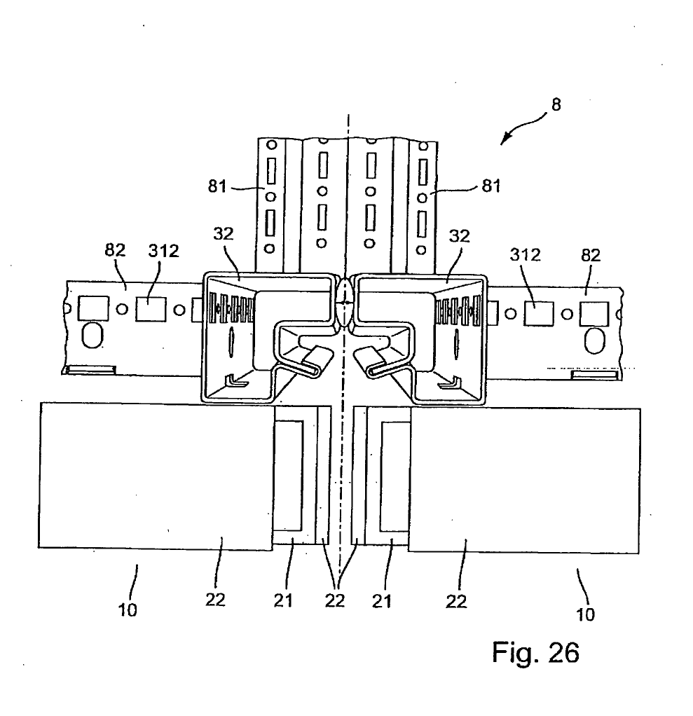

FIG. 27A a corner region of a socket having a mounting piece, a corner cover and two side covers in a schematic illustration in a perspective view,

FIG. 27B another corner region of a socket with switchgear cabinet fixed thereto, having a paneling piece and socket covers in a perspective schematic view,

FIG. 27C a corner cover in a top view,

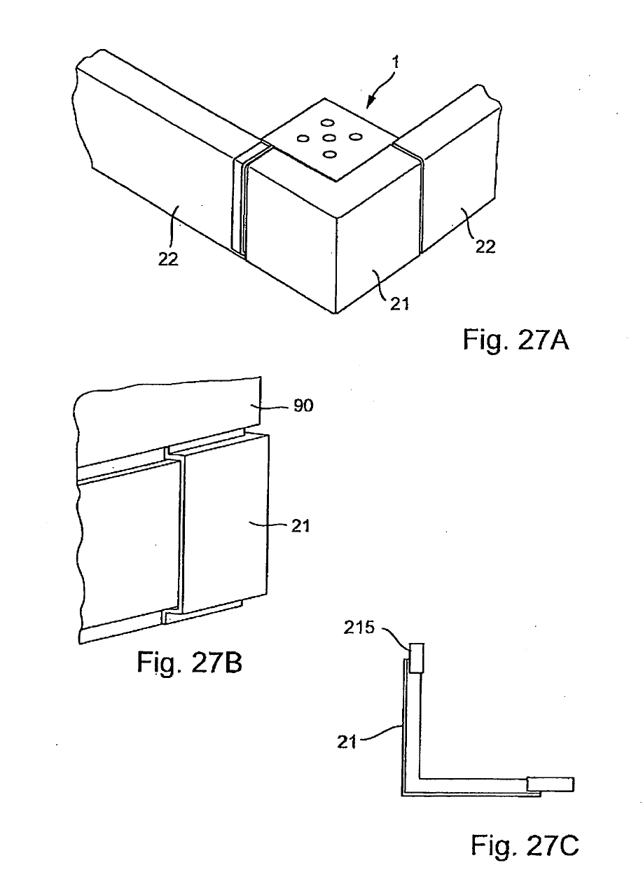

FIG. 28 a sectional view of a switchgear cabinet provided with lateral parts and a socket provided with covers in a perspective view and

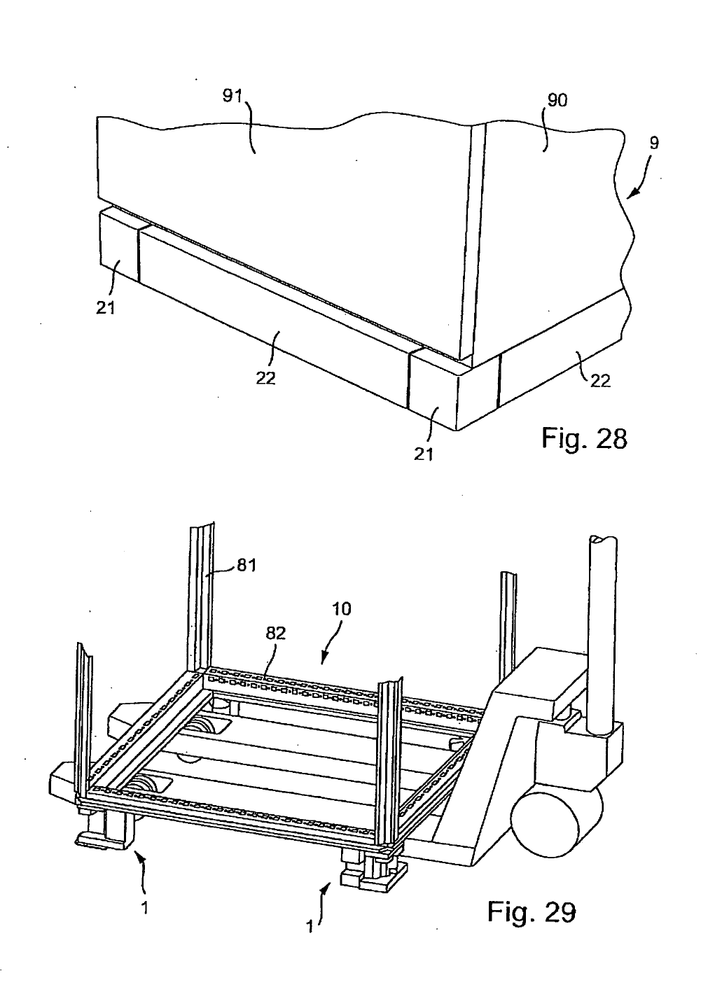

FIG. 29 a lower section of a framework mounted to a socket together with lifting arms of a lifting equipment which are introduced thereunder.

FIGS. 1A and 1B as well as also FIGS. 2A to 2F and 3A to 3F illustrate a mounting piece 1 in various views. Mounting piece 1 is used as a fundamental construction part of a construction unit, such as e.g. a socket 10 (e.g. FIG. 13 and FIG. 24A) or another mounting frame, for mounting to a switchgear cabinet or rack or another housing, preferably as a corner piece in the corner regions of the construction unit which is preferably rectangular or square in a top view. Mounting pieces 1 which are arranged in the corner regions are connected by longitudinal extending intermediate elements, such as mounting rails 32, rails 31 which are C-shaped in cross section (C-rails) and/or lateral covers.

Mounting piece 1 is formed as a molded part produced in a molding process, preferably as a plastic molded part or alternately as a metal molded part, in particular made of a nonferrous metal, for example of aluminum, or as a molded part of a compound material comprising fiber material which is artificial and/or consists of renewable raw materials which is e.g. embedded into a plastic matrix. It possesses a block-like, roughly rectangular or cubic shape with lateral parts oriented in three perpendicular space directions, x, y, z as apparent from FIG. 1A.

Preferably, the ratio of two respective pairs of dimensions in x-, y-, z direction is not more than 2:1, at best 3:1, the smallest dimension in one of the three space direction being at least 5 cm and the largest at most 20 cm. In a construction unit of the previously mentioned configuration with mounting pieces 1, the z direction of mounting piece 1 is perpendicular with respect to the rectangular or square, respectively, extension plane of the construction unit, while x- and y direction are running parallel to (or in, respectively) the direction of the sides of the construction unit.

As can be seen in the exemplary embodiment of FIGS. 1A and 1B as well as in FIGS. 2A to 2F and 3A to 3F, it is symmetrically formed with respect to a vertical diagonal plane extending in z direction which extends from an outer corner region 12 of the mounting piece 1 (referred to below as a first corner region) to the opposite inner corner region 11 of mounting piece 1 (referred to below also as a second corner region), as mounted in a construction unit, and is, on all outer sides, provided with receiving structures for mounting elements of different type, including for example also the mentioned rails 3, namely C-rails 31 and mounting rails 32, as well as arrangement of covers 2, in particular lateral covers 22 and corner covers 21 (cp. e.g. FIG. 16A).

As can be further seen in FIGS. 1A and 1B as well as in FIGS. 2A to 2F and 3A to 3F, first and second receiving chambers 132, 142 are formed which are recessed from a first mounting face 13 parallel to the x-z-plane, or lying there within, and from a second mounting face 14 parallel to the y-z-plane or lying therein, respectively, and which are oriented in x direction or y direction and are open at their front end facing the relevant mounting face 13 or 14, respectively, as well as to the opposite ends of mounting faces 13, 14. Having this configuration, end sections of rails 3 can be inserted from the relevant mounting face 13 or 14, respectively, so that even in an assembled state of a construction unit, later on rails 3 or similar intermediate elements can be added or removed. Moreover, rails 3 or the like can be introduced or inserted, respectively, through the open front ends, so that e.g. benefit of an initial mounting process of a construction unit may result. Furthermore, fixing elements are formed within the first and second receiving chambers 132, 142, which include first and second locking catches 135″, 145″ comprising preferably locking pins fixed to resilient tongues having locking slopes which are flat towards a relevant mounting face and locking steps which are steep inwardly, wherein the locking catches are perpendicular to the relevant mounting face 13, 14 in y direction or x direction, respectively, so that rails 3 or the like which are inserted from the relevant mounting face 13, 14 are retained in a locked manner against their insertion direction. The length of the locking catches to the steep locking steps is advantageously adjusted to established cross sections of rails 3 or distances to the rims of fixing holes arranged therein, so that rails 3 or the like intermediate elements are fixed in a correct position. The width of the locking catches 135″, 145″ extending in x direction or y direction, respectively, is further advantageous adjusted to the width of relevant rectangular or square fixing holes in particular of an established row 312 of holes. Moreover, also the dimensions of the receiving chambers 132, 142 are advantageously adjusted to the cross section contour of rails 3 or the like, so that a trouble-free insertion and a unique seat result.

Receiving chambers 132, 142 are surrounded by wall sections which are at the top and bottom sides with respect to the vertical direction (or z direction, respectively) and parallel to the x-y plane and by another wall section 137, 147 parallel to the relevant mounting face 13 or 14, respectively, wherein in the interior of receiving chamber 132, 142 in the exemplary embodiment as shown additionally reinforcing ribs are formed. The mentioned locking catches 135″, 145″ are e.g. formed at a bordering wall of the relevant receiving chamber 132, 142 parallel to the mounting face.

As e.g. can be clearly seen in FIG. 1A, further receiving chambers 131, 141 are provided behind the wall section 137 or 147, respectively, which is parallel to the relevant mounting face 13, 14 and which confine the relevant receiving chamber 132, 142 at its rear side, which receiving chambers 131, 141 are continuously confined by further wall sections, except for a gap 165 directed upwardly in z direction, and which are open only at their front ends towards the ends of mounting faces 13, 14 facing away from another. Likewise, rails 3, such as C-rails 31 or mounting rails 32 can be introduced or inserted, respectively, into these additional receiving chambers, namely from the top side through gap 165 or from the front side. Likewise, connecting elements are located within those receiving chambers 131, 141, for example additional resilient locking catches 135″, 145″ which are formed thereto which are adjusted to cross sectional contours of rails 3 or distances to hole rims, respectively, to fix rails 3 or the like. The connecting elements can further comprise fixing or positioning ribs which are adjusted to cross sectional contours of rails 3 or the like and which in addition result in a stiffening of wall sections. Moreover, fixing holes 111 may be provided for introducing further fixing elements into wall sections which are accessible from the outside. In an alternate embodiment (not illustrated), the additional receiving chambers 131, 141 or other additional receiving chambers can be open and accessible from inner sides spaced apart from the mounting faces.

Furthermore, the receiving structures on the mounting faces 13, 14 include further grooves 133, 143, additional locking catches 135, 145 or 135′, 145′, the latter extending along the relevant mounting faces 13, 14 in x direction or y direction, respectively, and comprising longitudinally extending grooves formed in ridge-shaped holdings at the outside of mounting faces 13, 14, wherein pairs of grooves having grooves open upwardly in a z direction and downwardly on the respective mounting face 13 or 14, respectively, which are preferably located in the same plane which is parallel to the x-z direction or y-z direction, respectively. Opposing locking noses which are formed e.g. on lateral covers 22 or corner covers 21, can be snapped into these pairs of grooves.

Furthermore, bolt-like locking catches 135, 145 having downwardly extending locking pins are formed on the outside of the mounting faces. Further, bar-like ribs 136, 146 are formed on the mounting faces 13, 14 running in x direction or y direction, respectively, which serve to position covers 2 and/or for stiffening. Furthermore, wall sections 137, 137′ surrounding receiving chambers 131, 132 or 141, 142, respectively, serve, apart from positioning, for stiffening mounting piece 1.

Mounting piece 1 is confined in z direction by a first base face 15 (at the bottom in a mounted state) and a second base face 16 (at the top in a mounted state) which form the outside of a first or second base wall section 150, 160, respectively, and extend in planes parallel to the x-y plane. Chamber-like cavities 153 (cp. also FIGS. 20) and 163 which are open to the outside, are formed perpendicular (in z direction) to the relevant base face 15, 16 in the base wall sections, which cavities are completely or partly confined (compared to the clear opening width) thin wall sections. Further, gaps 165 connected with receiving chambers 131, 141 lead into the second upper base face 1.6. Moreover, cylindrical holes or bores are formed into both base faces 15, in the exemplary embodiment as shown diagonally from the first to the second corner region 12, 11 as well as adjacent thereto extending in z direction, wherein at least some of the cylindrical bores 151, 161 are aligned to another within both base wall sections. As shown in FIG. 1A, a slot 152 is formed into the second corner region 11 in the first base wall section 140 transversely to the diagonal between the two corner regions 11, 12. Further, slot-like structures 162 are formed into the outside of the second base section 160. Further, structures protruding outwardly in z direction can be formed on the base faces 15, 16, in particular on the upper base face 16, such as protrusion 164 or bar-like protrusions 164′ (cp. FIG. 13) extending in x direction and in y direction, for uniquely positioning construction components to be mounted to the upper side of mounting piece 1, such as e.g. sections of a framework, a socket cover or adapter plates. Moreover, the above mentioned cavities 163 or 153, respectively, and bores 161, 151 can be used for positioning purposes.

As further shown in FIGS. 1A and 1B as well as in FIGS. 2A to 2F and 3A to 3F, three corner spaces 110 or 120, respectively, are formed within corner regions 11, 12. Here, further mounting elements can be inserted from the outside with free accessibility, wherein the corner space which is outside with respect to a construction unit can be covered with covers 2, in particular a corner cover 21.

The corner cover can be fixed on the one hand, e.g. with the aid of resilient locking elements formed on the interior side thereof and correspondingly positioned, having locking slopes on the input side and steep locking steps acting against the input direction at locking catches 135, 145 and on the other hand in grooves 133, 143 which are upwardly opened.

The first or outer, respectively, corner region 12 is formed in that mounting faces 13, 14 are spaced apart at their ends facing to another and form a free corner space in the corresponding first (in so far virtual) corner region 12 of mounting piece 1. First corner space 120 is separated from receiving chambers 132, 142 on both sides by means of respective corner region bordering walls 122, 122′, said corner region bordering walls 122, 122′ being perpendicular to the respective mounting face 13, 14 and oriented in z direction. In z direction, first corner space 120 is confined by first and second base wall sections 150, 160. Bores 151, 161 arranged in the base wall sections confining first corner space 120 are aligned. Further, open recesses 156 are introduced into a side of the lower base wall section 150 facing the first corner space, which are open from the walls laterally from the diagonal to the respective mounting face 13, 14, so that the corresponding bores 151 are better accessible for inserting mounting elements, as is shown in FIGS. 5A and 5B, wherein as a mounting element an adjustable leveling unit 62 is inserted into the aligned bores of the first and second base wall sections 150, 160. Both base wall sections 150, 160 form abutment rims for a cover defined at their outer rims, in particular for corner cover 21, so that a defined corner region is formed.

Second corner space 110 in (in so far virtual) second corner region 11 is formed in that additional wall sections integrally connect to the interior sides of the ends of first and second mounting face 13, 14, facing away from one another. As e.g. shown in FIG. 1A, the already described receiving chambers 131, 141 are arranged in these regions, wherein i.e. in the depth of the receiving chambers inwardly protruding wall sections are present. Between the wall sections, at the ends facing towards another, the second corner space 110 is formed as a free space. This free space is laterally confined by second corner region bordering walls 112, 112′ which are parallel to the adjacent mounting faces 13, 14 and oriented in z direction, and confined in z direction by means of the first and second base wall section 150, 160, wherein fixing holes 111 leading to receiving chambers 131, 141 are introduced are introduced into corner region bordering walls 112, 112′, and slot 152 is introduced into a side of the first base wall section 150 facing towards the second corner space 110, wherein an anchoring claw 41 having an angled flat retaining lug 410 (cp. FIG. 7) for anchoring an installed construction unit to a supporting surface can be inserted. In the second corner region 11, interior regions of both base sections 150, 160 of a construction unit are rounded (so that in this respect the mathematically precise corner is only virtual). Also second inner corner space 110 offers advantageous possibilities for mounting and can be easily accessed, e.g. from the interior of a switchgear cabinet after removal of a bottom plate which optionally covers a socket. Access is also created after removal of a lateral cover. Alternately, second corner space 110 can be formed by means of wall sections running at an angle with respect to x-y direction and z direction or by only one wall section running at an angle.

By means of base wall sections 150, 160 extending also across corner spaces 11, 12, large receiving regions for building extensions on both sides in z direction or a support on an underlay are achieved on their exterior or base face 15, 16, respectively. Cavities 153, 163 and bores 151, 161 having respectively relative thin wall sections result in stable support structures in particular in z direction as a honeycomb structure type, however, the cell-like cavities being not identical, but can be used as differently embodied functional regions with the receiving structures, including those regions of base wall sections 150, 160 extending across corner spaces 110, 120. In the center region between corner spaces 110, 120, the wall regions surrounding cavities 153, 163 or bores 151, 161, respectively, form optionally continuous supporting structures in z direction between both base faces 15, 16 or supporting structures supported by wall sections extending parallel to base faces 15, 16. Wall sections running in x direction and y direction are also relatively thin and result, together with reinforcing ribs, also in x direction and y direction a high stability with relatively small use of materials and accordingly relatively light construction of the mounting piece. In particular, if configured as a plastic molded part, apart from relatively thin wall sections, it is ensured that transition regions, such as crossing and corner regions between wall sections include material volumes as small as possible, so that the molding process is promoted at high dimensional stability. Structures and materials as mentioned, in particular plastics or composite materials, of the mounting piece 1 further result in benefits of vibration isolation with respect to vibrational and damping properties.

As shown in FIG. 4, identical or different mounting elements can be attached at mounting pieces 1 in different combination, wherein FIG. 4 shows covers 2, namely a corner cover 21 having a first and a second leg, as well as side covers 22 having a cover wall 220 and cover fixing elements 221 formed in the interior side facing to the mounting piece, rails 3, namely a mounting rail 32 having base legs 310, lateral legs 311 perpendicular thereto which in turn are provided with angled free end sections and rows 312 of holes provided in the base leg 310 and side legs 311, an anchoring means 4, namely an anchoring claw 41 having a front side flat retaining lug 410 at an angle, supporting means 6, namely a castor unit 61 with castor wheel 610, supporting plate 611 and retaining member 612, a leveling unit with leveling sleeve 620 and leveling bolts 621 as well as a cylinder-shaped thread insert 5 which can be inserted into a corresponding adapted bore 151, 161.

As shown in already mentioned FIGS. 5A and 5B, leveling unit 62 with leveling sleeve 620 and leveling bolt can be inserted e.g. into first corner region 12 when corner piece 1 is used e.g. for building up a socket 10. Leveling unit 62 protrudes into a bore existing at a respective location in upper base wall section 160, and with its adapted upper bolt section, into the lower section of leveling bolt 621 into bore 151 aligned therewith in z direction. For easy insertion, an open recess 156 is provided on the upper side of the lower base wall section 150 which is open towards the respective mounting face 13, 14. Leveling sleeve 620 is supported at those regions of base wall section 160 surrounding bore 161 with its band-like upper side, while leveling bolt 621 with its lower end section, protrudes respective bore 151 downwardly and can be screwed in or out more or less by means of a tool engaged on a hexagonal section of leveling unit 62.

FIG. 6 shows a supporting stand 63 inserted into first corner region 12 as a supporting means 6, having a stand plate and a stand pin 631 protruding through a corresponding bore 151.

FIG. 7 shows a corner region of a partly assembled construction unit, for example a socket 10, comprising a mounting piece 1, rails 3 connected thereto via receiving chambers 141, 142, namely a C-rail 31 and a mounting rail 32, and an anchoring means here in form of an anchoring claw 41 which engages slot 152 in lower base wall section 150 in the inner corner region 11 with an angled flat retaining lug 410, which slot is adapted thereto in size and shape to a large extent. Such a construction unit, a socket 10 or mounting frame, offers advantages in the installation of electrical components and/or air-conditioning components or energy storage components, e.g. for attachment, using retain struts, if needed, which can be easily mounted at mounting rails 32.

Also in construction units which are partly assembled and in sections shown in FIGS. 8A and 8B, a C-rail 31 and a mounting rail 32 are coupled to a mounting piece 1. A castor unit 61 is attached beneath mounting piece 1. Further, in FIG. 8B an anchoring claw 41 mounted to mounting piece 1 is illustrated.

FIGS. 9A to 9D show different embodiments of castor units 61 wherein in FIG. 9A a castor unit 61 mounted at a mounting piece 1 is illustrated. Castor unit 61 protrudes through a bore 151 in the lower base wall section 150 in inner corner region 110 with a bolt-shaped retaining member 612. The retaining member comprises some type of bayonet connection, bore 151 being accordingly adapted for passing a protruding cross bolt. FIG. 9B shows a correspondingly embodied castor unit 61 with supporting plate 612 and retaining member 612 with bayonet connection. FIG. 9C shows a castor unit with bayonet connection without supporting plate and FIG. 9D a castor unit with additional leveler with stand plate 630.

Alternate exemplary embodiments for castor units 61 are shown in FIGS. 10A and 10B which can be engaged and attached, with block-like retaining member 612′, laterally to wall regions of mounting piece 1 merging into the second corner region 11.

In FIGS. 11A and 11B, further sections of a corner region of a part assembled construction unit, for example a socket, are illustrated, wherein rails 3, namely C-rails 31 and mounting rails 32 are attached or can be attached, respectively, at both mounting faces 13, 14. FIG. 11C shows a corresponding lateral view. As apparent from the Figs., mounting rail 32 can easily be inserted into a respective receiving chamber 132 or 142, respectively of mounting piece 1 even later on after having removed an optionally existing cover. Mounting rail 32 locks onto resilient locking pin 135″ or 145″, respectively.

FIG. 12A shows a construction unit which is square in a top view, as an example a socket 10, with mounting pieces 1 arranged in four corner regions and intermediate elements in form of C-rails 31 and mounting rails 32 connecting them, as previously explained, coupled to corner pieces 1 with their end sections. FIG. 12B shows a socket 10 from one side while FIGS. 12C and 12D reproduce sections of the corner regions of socket 12 in an enlarged illustration. For example, relatively narrow configured C-rails 31 can be introduced with their narrow sides from above into gaps 165 and then, if needed after lateral displacement, be interiorly fixed in respective receiving chambers 131, wherein they are rearwardly engaged by relevant locking catches 135″ on their one side and are fixed (cp. also e.g. FIG. 1A). Advantageously, C-rails can be used in the socket region of a switchgear cabinet for securing lines, such as e.g. electrical cables. Rows 312 of holes having square or rectangular holes in a defined spacing and optionally intermediate round holes are advantageously aligned with corresponding holes or rows of holes, respectively, of mounting rails or frame profiles of the switchgear cabinet or the framework thereof, respectively. As may be recognized in FIG. 12D, the outside second corner region 120 is free for access from front end side, after optional covering cover elements have been removed.

A respective construction unit, for example a socket 10, as in FIG. 12A, is also shown in FIG. 13, but in a perspective top view. On the upper outside, a presently square support surface with receiving structures is formed, when in the outer frame region ledge-like protrusions 164′ extending in x direction and y direction are molded to the upper base wall section 160. Adjusting screws or connection screws are inserted into interior corner spaces 110 in relevant bores 151, as may be recognized from corner space 110 illustrated rearwardly in the Fig. (at the upper side on the drawing sheet).

FIGS. 14A and 14B show further exemplary embodiments of construction units in form of partly assembled sockets 10. In FIG. 14A, a rectangular socket having mounting rails 32 as connecting elements is shown, whereas FIG. 14B shows a square socket 10 having mounting rails 32 and C-rails 31 as intermediate elements or connecting elements, respectively. Respective corner pieces 1 are arranged in the corners according to the previously described embodiment.

FIGS. 15A and 15B, interned, show corner regions of a construction unit with mounting rails 32 or C-rails 31, respectively, coupled thereto. Thread inserts made of metal are inserted into some of the bores 161. An Allen screw is introduced into center bore 161, as shown in FIG. 15B. By taking those measures, mounting of e.g. a frame section of a frame work can be made on the upper side of the mounting piece. Protrusions 164, 164′ define abutment positions and result in a precise positioning.

FIG. 16A and 16B illustrate a cut-out of an arrangement of covers 2 at a mounting piece 1, wherein in FIG. 16A the corner region illustrated in FIG. 16B is enlarged. Cover arrangement 2 comprises two lateral covers 22 which are mounted to the mounting faces 13, 14 of mounting piece 1, as well as a corner cover 21 which covers the outer corner space 120 outwardly in an assembled state.

Preferably, lateral covers, as also shown in FIGS. 18A and 18B, are made as metal profile sections or preferably made of plastics (or even of compound material, such as fibers of artificial material or renewable raw materials embedded into a plastic matrix), comprising a flat cover wall 220 on their outside, wherein cover fixing element 212 or reinforcing ribs 222, respectively, are molded to the inner side. Stiffening ribs 222 or cover fixing elements 221 can also protrude perpendicular in the longitudinal edge regions of cover wall 220, as may be recognized in FIG. 16A. Also, cover fixing elements 221 may serve as reinforcing elements, so that it is possible to do without other individual stiffening ribs. Ledge-like cover fixing elements 221 are provided with locking pins at their free end sections comprising, towards their free end, e.g. in insert direction, flat insert slopes and, opposite to the insert direction, more or less steep locking flanges. Ledge-like cover fixing elements 221 advantageously form resilient locking tongues which can be deflected against their elastic spring forces. They cooperate with locking structures arranged at mounting faces 13 or 14, respectively, to which they are adapted. In the exemplary embodiment, this is achieved e.g. by ledge-like locking catches 135′, 145′ which are open downward or upward, respectively (with respect to the z direction) and which lockingly snap into oppositely directed locking pins of two respective cover fixing elements 221. Stiffening ribs 222 and ledges protruding from mounting faces 13, 14 may serve for stable support in a precise position. FIGS. 18A and 18B show lateral covers 22 from the inside or from the front end, respectively.

Preferably, also corner cover 21 is made as a molded part of metal or preferably of plastic (or even of the mentioned composite materials). First and second legs 210, 211 are also formed by a cover wall 220 which is flat on its outside and corresponds in its height (z direction) essentially to the height of the lateral covers 22. On the inner side of legs 210, 211, tongue-like or ledge-like protruding corner cover fixing elements 212 as well as ledge-like stiffening ribs 213 are molded, as can be seen in particular in FIGS. 17A to 17F. Corner cover fixing elements 212 form preferably resilient locking protrusions with locking pins molded to the cover wall, wherein two locking protrusions 212 spaced apart in z direction are oriented opposite to one another with their locking pins and snap into correspondingly positioned grooves or locking protrusions, respectively, on the mounting faces 13, 14, when inserted. Also, the locking pins of the corner cover fixing elements 212 are provided with flat insertion slopes in insert direction and preferably also carry steeper locking flanges on their sides arranged opposite to the insert direction. For example, locking catches 135, 145 and 133, 143 on the outside of mounting faces 13, 14 serve as locking protrusions for snapping in corner covers 21.

Advantageously, the covers can be formed to perform switchgear cabinet functions, for example can be provided with ventilation openings and/or recesses or receptacles of grids, conditioning mats, fans or the like.

FIG. 19A shows a cut-out of a corner region of a construction unit comprising mounting rails 32 and C-rails 31 mounted to a mounting piece 1 as well as removed lateral covers 22 and a corner cover 21. FIG. 19B shows a socket 10 having covers 21, 22 mounted thereto and comprising C-rails 31 and mounting rails 32. Corner covers 21 cover the respective outer corner spaces 120 of corner pieces 1. Lateral covers can additionally abut at intermediate elements, for further support, in particular to mounting rails 32, and can optionally be locked therewith. Thereby, an additional stabilization of lateral covers 22 is achieved.

FIG. 20 shows a cut-out of another corner region of a construction unit. Herein, a mounting rail 32 and a C-rail 31 are mounted to a mounting piece 21 which their end sections at receiving chambers 141, 142 at the mounting face 14 of mounting piece 1. In the lower region of mounting face 13, a wider mounting rail 32′ is inserted into respective locking protrusions or grooves, respectively, and protrudes with its edge region facing away from the mounting face 13 so that it can be engaged with corresponding receiving structures on the mounting face of a neighboring corresponding mounting piece 1. In this way, a side-to-side sequence of construction units, such as e.g. sockets, in a defined arrangement and with stable connection is achieved. This is shown in FIG. 21, where the wide mounting rail 32′ protrudes into the respective receiving chambers of neighboring mounting faces of two mounting pieces 1 and is locked therein. For locking, again protruding locking catches can be used which are molded to the mounting faces 13, 14 of mounting pieces 1 and which interact with holes of rows 312 of holes positioned in mounting rail 32′.

FIGS. 22A and 22B show various adapter elements 7 including adapter plates 70, 70′ and connecting elements 71 adjusted therewith. FIG. 22A shows a substantially triangular adapter plate 70, whereas FIG. 22B shows a rectangular adapter plate 70′. The adapter plates comprise fixing holes as well as protruding protrusions on their flat sides. The protrusions and fixing holes are adjusted with complementary impressions on the upper and/or lower based surface 15, 16 of the mounting piece 1, e.g. also on their rim region, wherein the fixing holes are also aligned with suitable bores within the base surfaces 15, 16. By means of those or similar adapter plates, adjustments to various structures are coupled to mounting pieces 1 via adapter plates.

FIG. 22C shows a corner region of a framework 8 of a switchgear cabinet which has a vertical frame profile 81 and horizontal frame profiles 82, mounted or to be mounted on a mounting piece which is not shown. On the left hand side, a schematic cross section illustration of the vertical frame profile 81 is illustrated, wherein two essentially square or rectangular hollow chambers or profile sections 810, respectively, are connected to another via a diagonally extending connecting web 811. Having such a profile cross section, free spaces on the outside in a vertical edge region of a framework or switchgear cabinet, which are inside and outside, are formed which form advantageous mounting spaces for mounting installation elements, such as e.g. connection elements for side planking, hinges or locking elements. If the profile sections 810 are provided with narrow abutment or sealing ledges protruding outwardly, advantages are generated for close row mounting, as it is known from relevant applications of the applicant. The free space formed in the edge region is systematically preceded within vertical direction when assembling a construction unit or a socket 10 of the previously described construction with mounting pieces 1 comprising free corner spaces 120 in outer corner regions. Thereby, assembling benefits are generated.

FIG. 22D shows an example for using a bearing sleeve in a bore of corner piece 1 which may advantageously be used for receiving a connecting pin, for example of a castor unit 61 or a supporting stand 63.

FIG. 23 shows row mounting of two mounting pieces 1 in z direction. Receiving structures on both base faces 15, 16 are adjusted to another so that the mounting pieces placed one above the other do not displace in x- and y direction and can easily be connected e.g. by means of a screw inserted into the corner spaces 110, 120 which (unv.) through the aligned bores 151, 161, as can be seen in FIG. 23, in particular, if thread inserts are inserted into bores 161 of the upper base wall section 160. In this way, construction units, such as e.g. socket 10, can be combined in a double or multiple row mounting and may reach a multiple height. They can be easily covered with respective covers of the previously mentioned constructions or with double or multiple covers.

FIG. 24A shows a lower section of a framework 8 of a rack or a switchgear cabinet mounted on a socket 10 with mounting pieces 1. The framework comprises vertical and horizontal frame profiles 81, 82 of the previously mentioned type, wherein vertical profiles 81 form free spaces in the outer edge region and inner edge region resulting in advantages assembling possibilities, as previously explained. The mounting pieces in turn offer free corner spaces 110, 120, as described. Mounting rails 32 are provided with rows 312 of holes having the same spacing as the hole screen provided in horizontal frame profiles 82 and vertical frame profiles 81, wherein hole screens of mounting rails 82 and horizontal frame profiles 82 are aligned with another at least in a vertical direction. Further, C-rails 31 for securing lines, in particular cables, are inserted into mounting pieces 1, as also previously explained. In the inner corner space of vertical frame profiles 81, connection screws are inserted into stabilizing receptacles positioned therein which proceed on the lower side of a lower frame of framework 8 formed by horizontal frame profiles 82 and engaged in accordingly positioned bores 161 with thread inserts 5 introduced therein. Connecting screws passing there through are advantageously positioned in the outer corner region 12 or the outer corner space 120, respectively. The upper side of the upper base surface 16 of mounting piece 1 is adapted to the bottom side of horizontal profiles 82 regarding its receiving structure, so that e.g. protrusions may engage into corresponding holes and/or the outer corner region of horizontal profiles 82 is in sections confined by outer ledge-like protrusions 164. FIG. 24B shows a lateral view of the lower section of framework 8 mounted on the socket, FIG. 24C a top view, and FIGS. 24D and 24E show, enlarged a corner region in a lateral view or in perspective view, respectively. Framework 8 can be connected with corner pieces 1 by means of screws, locking elements or clip elements and/or clamping elements.

FIG. 25 shows another corner region of a framework 8 having horizontal frame profiles 82 and a vertical frame profile 81, mounted on a socket 10, wherein a horizontal profile extending perpendicular to the drawing plane is illustrated in cross section. It forms in its virtual outer edge region a continuous free space where only a ledge-like connection section is protruding, moreover, also in this region beneficial mounting possibilities are offered. The flat bottom side of horizontal profiles rests stably on the top surface of the socket, in particular also on the mounting pieces 1 (not shown in this illustration).

FIG. 26 shows a side-to-side arrangement with two neighboring sockets and frameworks 8 in a corner region. Horizontal frame profiles are opposite to one another, having narrow abutment bars between which a sealing element is introduced. They rest stably on a respectively associated top surface of two sockets 10 with their flat bottom surface. A row of sockets of e.g. benefits in pre-installation, so that frameworks or switchgear cabinets or racks in a row can be easily positioned and only need to be fixed.

FIGS. 27A, 27B and 27C show corner region of a socket with a schematically illustrated mounting piece 1 to which a cover arrangement having lateral covers 22 and a corner cover 21 is mounted. In FIG. 27B, further a part of a switchgear cabinet wall arrangement 9 with switchgear cabinet wall element 90 is shown. FIG. 27C shows a corner cover 21 in a sectional view, wherein free end sections are offset inwardly by about the thickness of the wall section in a Z-shaped manner, so that the lateral blends can overlap the offset free end sections of corner covers 21, so that a flushing transition of the outer surfaces is achieved.

FIG. 28 shows a cut-out of a socket having lateral covers and corner covers, enlarged with respect to FIG. 27A, as well as a cut-out of a switchgear cabinet having a switchgear cabinet wall arrangement 9 with switchgear cabinet wall elements 91 and e.g. a door 91.

FIG. 29 shows a lower framework section mounted to an uncovered socket with mounting pieces 1, where in a socket region levers of lifting equipment are introduced. Mounting pieces 1 form advantageous distance pieces for introducing the levers similar to a pellet. Thereby, transporting benefits are generated.

A construction unit assembled by means of mounting pieces 1 can not only be used as a socket 10, but for example also as an intermediate frame between the frameworks 8 mounted above the other, or as a top part frame. Even a use as mounting frame is conceivable. The z direction of the mounting pieces may be oriented in horizontal direction, or the plane of the construction unit, such as mounting frame, may be vertically oriented.

1-12. (canceled)

13. A socket or a mounting frame for a switchgear cabinet or a rack, comprising mounting pieces which are arranged, as corner pieces, in the corner regions of a rectangle or square that extends in an x-y plane, said mounting pieces being produced in a respective shaping process and comprising first and second mounting faces which lie outside with respect to the rectangle or square, which extend in the x direction and in the y direction at a right angle thereto and which extend in a space direction z at a right angle to the x-y plane, wherein sections of a system of covers are brought into contact with the mounting faces, said covers having lateral covers with cover walls that are flat on the exterior and that have reinforcing ribs extending longitudinally on the interior, and being fastened to receiving structures of the mounting pieces by connecting means, wherein the lateral covers have cover fastening elements formed onto the interior of the lateral covers by which they are fastened directly or indirectly to the receiving structures of the mounting pieces by means of said cover fastening elements, wherein the cover fastening elements extend in longitudinal direction of the lateral covers on an interior of the cover wall, wherein the cover fastening elements protrude perpendicularly from the interior of the cover wall to form reinforcing elements and that the lateral covers are made of metal or preferably of plastics in an extrusion process, and wherein the lateral covers are selectively provided with longitudinally running reinforcing ribs on the interior of the cover wall.

14. The socket or mounting frame of claim 13, wherein the cover fastening elements are formed as clip elements or locking elements having a flat insert slope and a steep locking step and are engaged or can be engaged, by means of resilient deflection, with respectively adapted receiving structures at the mounting faces of the mounting pieces or at other intermediate elements, such as mounting rail or C-rail, extending between the mounting pieces and mounted thereto with their end sections, to fix the lateral covers, wherein the cover fastening elements and/or the receiving structures can be resiliently deflected.

15. The socket or mounting frame of claim 14, wherein the intermediate elements comprise a mounting rail or C-rail.

16. The socket or mounting frame of claim 13, wherein the system of covers also includes corner covers which are configured to cover the outer corner regions of the mounting pieces.

17. The socket or mounting frame of claim 16, wherein the corner covers are provided with corner cover fastening elements formed onto the interior thereof by which they can be fastened directly or indirectly to associated receiving structures of the mounting piece.

18. The socket or mounting frame of claim 16, wherein the corner covers are made of metal and are provided with reinforcing structures formed onto the interior of plate-shaped corner cover walls thereof.

19. The socket or mounting frame of claim 16, wherein the corner covers are made of plastics and are provided with reinforcing structures formed onto the interior of plate-shaped corner cover walls thereof.

20. The socket or mounting frame of claim 17, wherein the corner covers, in order to achieve at a smooth transition from an exterior thereof to the exterior of the lateral covers, comprise end sections overlapping facing end sections of the lateral covers, which are inwardly offset by the thickness of the cover wall in a z shaped manner.

21. The socket or mounting frame of claim 13, wherein the receiving structures of the mounting pieces comprise receiving chambers running parallel to the relevant mounting face, which are at least partly surrounded by wall sections running in their orientation direction and which are open at their front ends facing away from each other, and/or that the receiving structures comprise receiving ribs, receiving grooves, receiving bars, other protrusions and/or other depressions and that at least a proportion of the receiving structures is provided with fastening means which can be engaged with the covers and/or with intermediate elements extending between the mounting pieces.

22. The socket or mounting frame of claim 21, wherein the fastening means comprises locking means formed on the receiving structures.

23. The socket or mounting frame of claim 13, wherein the mounting pieces terminate in z direction in a first and a second base face oriented in the x-y plane, the second base face being parallel and spaced apart from the first base face by a distance, both forming the outer face of at least a first and at least a second base wall section, and that the mounting faces are spaced apart from another at their ends facing towards another and form a first corner space in the relevant first virtual corner region of the mounting piece which can be covered with the covers of the system.

24. The socket or mounting frame of claim 23, wherein further wall sections are coupled to the interior of the ends of the first and second mounting face, which ends are facing away from another, said wall sections being integrally connected and leave a second corner space between their ends facing towards another, which is confined in z direction by the first and the second base wall section.

25. The socket or mounting frame of claim 13, wherein the mounting pieces are shaped as block-like plastic molded parts.

26. The socket or mounting frame of claim 13, wherein, for producing a frame of double or multiple height, two or more mounting pieces are respectively arranged in the corner regions in z direction and are connected to another.
